(19) United States
(12) Patent Application Publication
(10) Pub. No.: US 2010/0084710 A1
(43) Pub. Date: Apr. 8, 2010

(54) Capacitor-Less Dynamic Random Access Memory (DRAM) Devices

(76) Inventors: Sung-hwan Kim, Gyeonggi-do (KR); Yong-chul Oh, Gyeonggi-do (KR); Hoon Jeong, Gyeonggi-do (KR); Sung-in Hong, Seoul (KR); Yong-Iack Choi, Seoul (KR); Ho-ju Song, Seoul (KR)

Correspondence Address: MYERS BIGEL SIBLEY & SAJOVEC, PO BOX 37428, RALEIGH, NC, 27627, US

(21) Appl. No.: 12/564,533

(22) Filed: Sep. 22, 2009

(30) Foreign Application Priority Data
Oct. 7, 2008 (KR) 2008-98158

(51) Int. Cl. H01L 27/12; H01L 29/786

(52) U.S. Cl. 257/347; 257/E27.112; 257/E29.287

(57) ABSTRACT

Dynamic random access memory (DRAM) devices including an insulating layer on a semiconductor substrate; a silicon layer on the insulating layer; an active region in the silicon layer; and a unit cell of a transistor on the active region are provided. The DRAM device does not include a capacitor.

### CLAIM OF PRIORITY

This application claims the benefit of Korean Patent Application No. 10-2008-0098158, filed on Oct. 7, 2008, in the Korean Intellectual Property Office, the disclosure of which is incorporated herein in its entirety by reference.

### FIELD

The present invention relates generally to semiconductor devices and, more particularly, to dynamic random access memory (DRAM) devices.

### BACKGROUND

Generally, a memory cell in a dynamic random access memory (DRAM) device includes a field effect transistor (metal oxide semiconductor (MOS) transistor, hereinafter, referred to as a transistor) to control read/write operations, and a capacitor to store electric charges. Integration of the DRAM device has increased as the size of transistors has been reduces. Furthermore, integration of the DRAM device has been improved due to capacitor formation technologies directed to an effective capacity of the capacitor in a small area, for example, technologies for forming a stack capacitor or a deep trench capacitor, technologies for forming a dielectric layer of the capacitor using a high-k layer, and technologies for increasing a surface area of a lower dielectric layer in the capacitor.

Short channel effects caused by the reduced size of the transistor and increase of fabrication costs due to the complex capacitor formation may obstruct further improvement of the integration of DRAM devices. Therefore, various technologies for changing, the structures of DRAM devices have been suggested.

### SUMMARY

Some embodiments of the present invention provide dynamic random access memory (DRAM) devices including an insulating layer on a semiconductor substrate; a silicon layer on the insulating layer; an active region in the silicon layer; and a unit cell of a transistor on the active region. The DRAM device does not include a capacitor.

In further embodiments of the present invention, the unit cell of the transistor may include a gate stack on the active region; a source region and a drain region in the silicon layer under both walls of the gate stack; a body region between the source region and the drain region; a source contact pad and a drain contact pad on the source region and the drain region, respectively; and a bit line and a source line connected to the source contact pad and the drain contact pad, respectively.

In still further embodiments of the present invention, the body region may be electrically floated by junctions between the source/drain regions and the body region, and by the insulating layer.

Some embodiments of the present invention provide a DRAM device including an insulating layer on a semiconductor substrate; a plurality of silicon layers on the insulating layer; a plurality of first active regions in the silicon layers on the insulating layer in a first direction; a plurality of second active regions in a second direction to be separated from the first active regions in the first direction, wherein the first direction is perpendicular to the second direction; a plurality of word lines in the second direction across the plurality of first active regions and the plurality of second active regions and separated from each other in the first direction; a plurality of source lines between the word lines to be parallel with the word lines and connecting to some parts of the first active regions and the second active regions between the word lines; and a plurality of bit lines in the first direction along with the first and second active regions and connecting to some parts of the first and second active regions. The DRAM device does not include a capacitor.

In further embodiments of the present invention, the source lines may be connected to source line contacts in the first active regions and the second active regions located on side portions of the word lines.

In still further embodiments of the present invention, the bit lines may be connected to bit line contacts in the first active regions and the second active regions located on side portions of the word lines.

In some embodiments of the present invention, the bit line contacts may be source contact pads that are on the first and second active regions and bit line contact pads on the source contact pads.

Further embodiments of the present invention provide an insulating layer on a semiconductor substrate; a plurality of silicon layers on the insulating layer; a plurality of first active regions in a direction that is diagonal to a first direction, which is parallel with the silicon layers on the insulating layer, and separated from each other in the first direction; a plurality of second active regions separated from the first active regions in a second direction that is perpendicular to the first direction; a plurality of word lines in the second direction across the first and second active regions and separated from each other in the first direction; a plurality of bit lines in the second direction and connecting to the first and second active regions through bit line contacts; and a plurality of source lines to be perpendicular to the word lines and the bit lines and connecting to the first and second active regions between the word lines through source line contacts. The DRAM device does not include a capacitor.

In still further embodiments of the present invention, the source line contacts may be drain contact pads on the first and second active regions and source line contact pads on the drain contact pads.

In some embodiments of the present invention, the bit line contacts may be in the second direction along with the first and second active regions, and the source line contacts may be in the first direction along with the first and second active regions.

### BRIEF DESCRIPTION OF THE DRAWINGS

Exemplary embodiments of the inventive concept will be more clearly understood from the following detailed description taken in conjunction with the accompanying drawings.

FIGS. 1 and 2 are cross sections illustrating a unit memory cell in adynamic random access memory (DRAM) device according to some embodiments of the present invention.

FIG. 3 is a graph illustrating a drain current according to a gate voltage of the unit memory cell in the DRAM device of FIGS. 1 and 2 in accordance with some embodiments of the present invention.

FIG. 4 is a layout of memory cells in the DRAM device according, to some embodiments of the present invention.

FIG. 5 is an enlarged view of a portion of the DRAM device illustrated in FIG. 4.

FIG. 6 is a cross section illustrating a portion of the DRAM device taken along the line X-X′ of FIG. 5 in accordance with some embodiments of the present invention.

FIGS. 7 and 8 are cross sections of the DRAM device taken along the line Y-Y′ of FIG. 5 in accordance with some embodiments of the present invention.

FIG. 9 is a layout illustrating a memory cells in a DRAM device according to some embodiments of the present invention.

FIG. 10 is an enlarged view of a portion of the DRAM device of FIG. 9 in accordance with some embodiments of the present invention.

FIG. 11 is a cross section illustrating the DRAM device taken along the line X-%′ of FIG. 9 in accordance with some embodiments of the present invention.

FIGS. 12 and 13 are cross sections illustrating the DRAM device taken along line Y-Y′ of FIG. 9 in accordance with some embodiments of the present invention.

FIG. 14 is a layout of a DRAM device.

FIG. 15 is a cross section illustrating the DRAM device taken along, line X-X′ of FIG. 14 for illustrating an electric interference between memory cells in the DRAM device accordance with some embodiments of the present invention.

FIG. 16 is a graph illustrating an electric current according to a voltage in the DRAM device of FIG. 14.

FIG. 17 is a plan view of a memory module using the DRAM chip according, to some embodiments of the present invention.

FIG. 18 is a block diagram of an electronic system including the DRAM chip according to some embodiments of the present invention.

### DETAILED DESCRIPTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening, elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

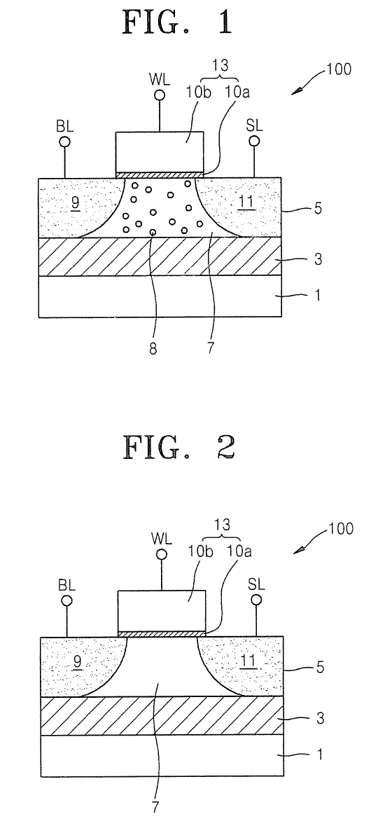

Structures of memory cells and operating processes of a capacitor-less DRAM device (hereinafter, referred to as “DRAM device”) according to some embodiments of the present invention will be discussed herein with respect to FIGS. 1 through 18 below. As used herein, the terms source and drain may be used interchangeably.

FIGS. 1 and 2 are cross sections of a structure of a memory in the DRAM device according to some embodiments of the present invention. Referring now to FIG. 1, a unit memory cell 100 in the DRAM device of some embodiments of the present invention includes a semiconductor substrate 1, on which an insulating layer 3, for example, a silicon oxide layer, is formed, and an n-type source region 9, an n-type drain region 11 and a p-type body region 7 in a silicon layer 5 on the insulating layer 3. The semiconductor substrate 1 may be a p-type silicon wafer (p-type silicon substrate). The silicon layer 5 is an active region in the DRAM device.

The silicon layer 5, the insulating layer 3, and the semiconductor substrate 1 may be provided from a silicon-on-insulator (SOI) substrate. The insulating layer 3 may be a buried oxide (BOX) layer that is formed using a separation via an implanted oxygen (SIMOX) method or a bonding and layer transfer method. The insulating layer 3 may be an oxide layer formed using a chemical vapor deposition process.

The source region 9 and the drain region 11 may be formed throughout the entire thickness of the silicon layer 5. The body region 7 is disposed between the source region 9 and the drain region 11, and is electrically floated by junctions between the source/drain regions 9 and 11 and the body region 7, and by the insulating layer 3. The body region 7, the source region 9, and the drain region 11 may be formed in the active region like in the general transistor. A gate stack 13 including a gate insulating layer 10a and a gate electrode 10b is disposed on the body region 7. A word line WL is connected to the gate stack 13, and a bit line BL and a source line SL are respectively connected to the source region 9 and the drain region 11.

When predetermined control signals and bias voltages are applied to the gate stack 13, the source region 9, and the drain region 11, respectively, an impact ionization may occur around the bonding region between the source region 9 and the drain region 11 and the body region 7. Also a gate induced drain leakage (GIDL) caused by a band to band tunneling may occur. Excessive charges 8 generate in the floating body region 7 due to the impact ionization or the GIDL, and the charges 8 may be stored in the floating body region 7 as shown in FIG. 1 to represent logic 1 data status, or the charges 8 may be discharged to the source region 9 and the drain region 11 as shown in FIG. 2 to represent logic 0 data status.

For example, when the body region 7 is of a p-type and the source region 9 and the drain region 11 are of an n-type, the impact ionization may occur due to hot electrons around the bonding region with the source region 9 and/or the drain region 11. The impact ionization generates pairs of electrons-holes, and the generated holes 8 are accumulated in the body region 7 to represent the logic 1 status as shown in FIG. 1. In addition, when a positive bias voltage is applied to the bonding between the body region 7 and the source region 9 or the drain region 11, the holes 8 accumulated in the body region 7 are discharged to the source region 9 and the drain region 11 to represent the logic 0 data status.

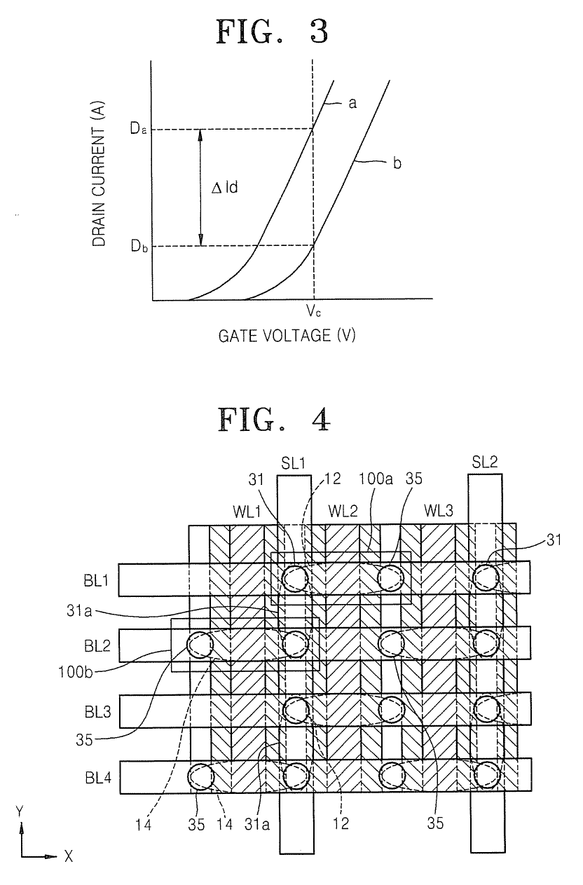

FIG. 3 is a graph illustrating a drain current according to a gate voltage in the unit memory cell of the DRAM device illustrated in FIGS. 1 and 2. In particular, the memory cell 100 in the DRAM device according to some embodiments of the present invention may be in the data states of logic 1 and logic 0 according to a potential of the body region 7 as illustrated in FIGS. 1 and 2. In the graph, the curve a denotes the drain current according to the gate voltage in the logic 1 status shown in FIG. 1, and the curve b denotes the drain current according to the gate voltage in the logic 0 status shown in FIG. 2. As shown in FIG. 3, the logic status of the body region 7 is determined with reference to a difference (AId) between the drain currents Da and Db when a predetermined gate voltage Vc is applied.

As discussed above, the recording status of the unit memory cell 100 in the DRAM device according to some embodiments of the present invention may be determined by detecting the difference in the drain currents according to the density of holes accumulated in the body region 7. Furthermore, since the unit memory cell of the DRAM device includes the body region 7 that stores the charges, a process of forming the capacitor, which is complex, may be omitted. Accordingly, the integration of the DRAM device according to some embodiments of the present invention may be improved, and the DRAM devices may be produced economically.

A layout of the memory cells in the DRAM device according to some embodiments of the present invention for realizing the memory cells and physically distinguishing the memory cells so that an interference does not occur between the memory cells and a structure of the memory cell will be discussed further below.

Referring now to FIG. 4, a layout of the memory cells in the DRAM device according to some embodiments of the present invention will be discussed. In particular, the DRAM device according to the present embodiment includes a plurality of memory cells. In FIG. 4, two memory cells are shown and denoted by reference numerals 100a and 100b. The DRAM device includes a plurality of first active regions 12, which are separated from each other in a first direction (X direction). The first active regions 12 are formed on the silicon layer 5 that is disposed on the insulating layer 3 of the semiconductor substrate 1 as described above.

Second active regions 14 are formed to be separated from each other in a second direction (Y direction) that is perpendicular to the first direction. The second active regions 14 are formed on the silicon layer 5 that is disposed on the insulating layer 3 of the semiconductor substrate 1. The first active regions 12 and the second active regions 14 are located so that end portions of the first and second active regions 12 and 14 correspond to each other. The first and second active regions 12 and 14 are located repeatedly in the first and second directions, respectively. The memory cells, for example, memory cells 100a and 100b are formed on the first and second active regions 12 and 14.

Word lines WL1-WL3 are formed across the first and second active regions 12 and 14 in the second direction and separated from each other in the first direction. The word lines WL1-WL3 perform as gate electrodes by including the gate stack (13, refer to FIGS. 1 and 2).

Source lines SL1-SL2, that are formed in parallel with the word lines WL1-WL3 in the second direction and connected to some parts of the first and second active regions 12 and 14 between the word lines WL1-WL3, are formed between the word lines WL1-WL3. The source lines SL1-SL2 are connected to the active regions 12 and 14 through source line contacts 31. The source line contacts 31 may be formed on the two memory cells 100a and 100b, or may be formed throughout the two memory cells 100a and 100b as denoted by reference numeral 31a in FIG. 4. The source lines SL1-SL2 are connected to source regions (not shown), which are formed on the first and second active regions 12 and 14.

Bit lines BL1-BL4 are formed in the first direction along the first and second active regions 12 and 14, and the bit lines BL1-BL4 are connected to the first and second active regions 12 and 14 through bit line contacts 35. The bit lines BL1-BL4 are connected to drain regions (not shown) that are formed on the first and second active regions 12 and 14.

In the memory cells 100a and 100b having the above described structure, one unit transistor is formed in one active region, that is, each of the first and second active regions 12 and 14. For example, in the memory cell 100a of the DRAM device according to the present embodiment, the word lines WL2 is formed on one active region 12, the bit line BL is connected to a part of the first active region 12, which is located on a side of the word line WL2, and the source line SL1 is connected to a part of the first active region 12, which is located on the other side of the word line WL2. As described above, according to the memory cells 100a and 100b in the DRAM device, one transistor is realized on one active region so that an electric interference does not occur between the memory cells 100a and 100b. Cross-sections of the memory cells will be discussed further below.

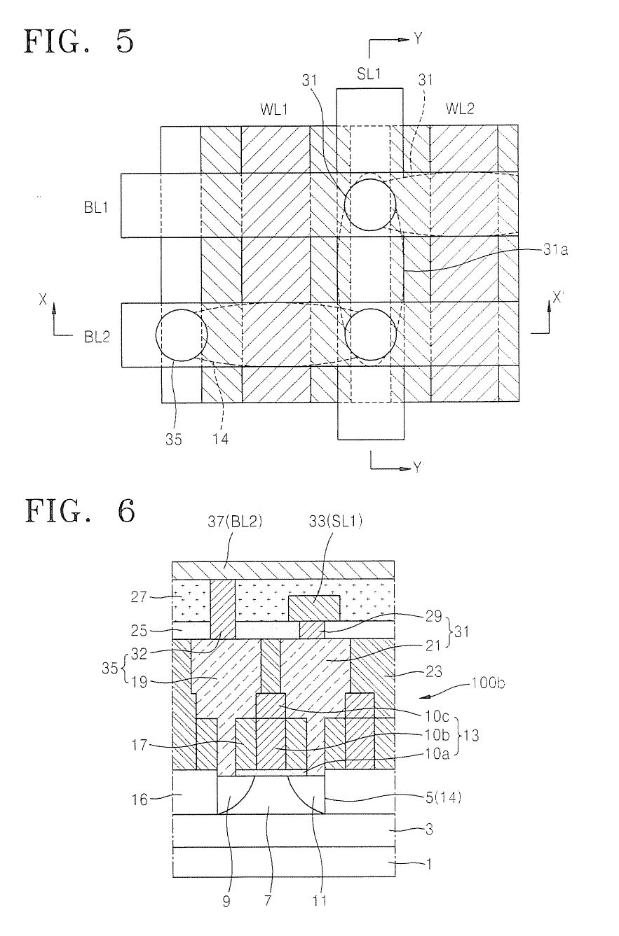

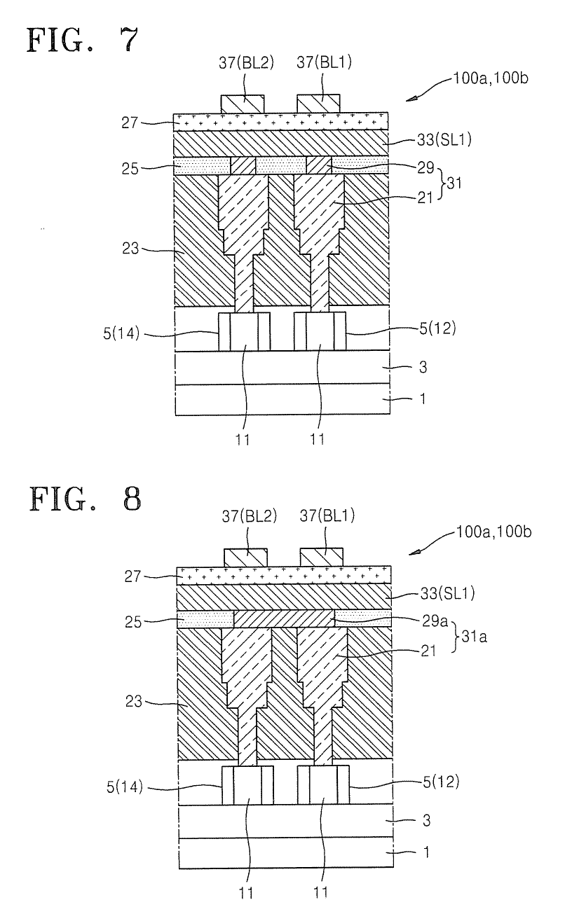

FIG. 5 is a partial enlarged view illustrating a portion of FIG. 4. FIG. 6 is a cross section of the DRAM device of FIG. 4. FIGS. 7 and 8 are cross sections of the DRAM device taken along line Y-Y of FIG. 5.

As illustrated in FIG. 6, in the memory cell 100b of the DRAM device, the silicon layer 5 is formed on the semiconductor substrate 1, on which the insulating layer 3 is formed. The silicon layer 5 may be a p-type silicon layer. The silicon layer 5 becomes the active region 14, on which the memory cell 100 is realized. The active region 14 is insulated by a device isolation layer 16 that surrounds the active region 14. One unit transistor is formed on one active region 14.

The unit transistor includes the gate stack 13, the source region 9, and the drain region 11 that are formed on the active region 14, and the body region 7 formed between the source region 9 and the drain region 11. The source region 9 and the drain region 11 may be of n-type. The gate stack 13 may include the gate insulating layer 10a, the gate electrode 10b, and a capping layer 10c. Spacers 17 are formed on both walls of the gate stack 13. The source region 9 and the drain region 11 are formed in the active region 14 that is located on lower portion of the gate stack 13 and the spacers 17.

A source contact pad 19 and a drain contact pad 21 are formed on the source region 9 and the drain region 11, respectively. The source contact pad 19 and the drain contact pad 21 are insulated by a first interlayer dielectric 23. The bit line (BL2) 37 and the source line (SL1) 33 are connected to the source contact pad 19 and the drain contact pad 21 respectively through a bit line contact pad 32 and a source line contact pad 29. The bit line 37 and the source line 33 may be directly connected to the source contact pad 19 and the drain contact pad 21 without using the bit line contact pad 32 and the source line contact pad 29.

The source contact pad 19 and the bit line contact pad 32 form a bit line contact 35, and the drain contact pad 21 and the source line contact pad 29 form a source line contact 31. The bit line contact 35 and the source line contact 31 are insulated by a second interlayer dielectric 25 and a third interlayer dielectric 27.

In FIG. 7, the source line contact pad 29 is formed in the memory cells. As illustrated in FIG. 7, the source line contact pads 29 are formed in both of the memory cells 100a and 100b, and thus, the source line contact 31 is formed of the drain contact pad 21 and the source line contact pad 29.

As illustrated in FIG. 8, a source line contact 31a is shared by the memory cells. A source line contact pad 29a that connects the memory cells to each other is formed, and then, the source line contact 31a is formed of the drain contact pad 21 and the source line contact pad 29a.

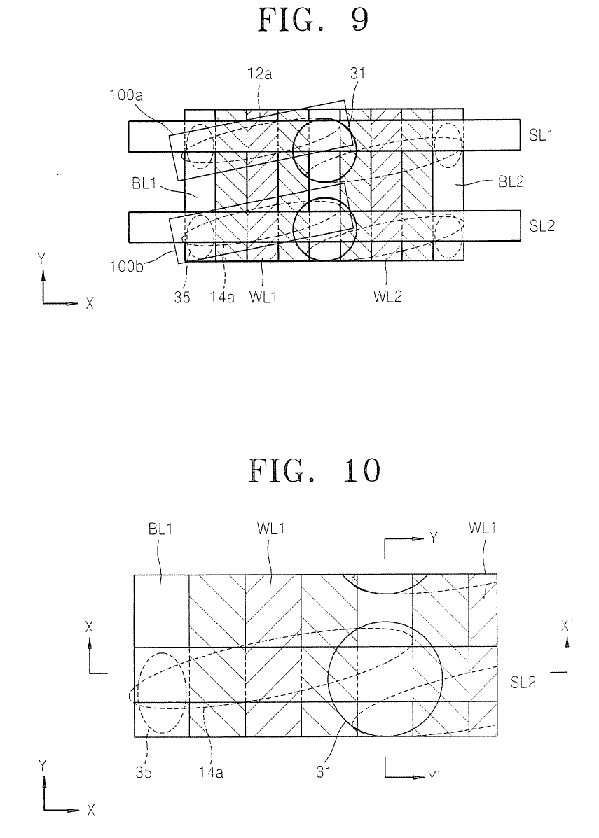

FIG. 9 is a layout of memory cells in a DRAM device according to some embodiments of the present invention. In particular, the DRAM device of FIG. 9 is similar to the device discussed above except that first active regions 12a and second active regions 14a are disposed in a direction that is diagonal to the first direction (X direction), and directions in which the bit lines BL1-BL2 and source lines SL1-SL2 are formed are changed.

The DRAM device according to some embodiments of the present invention includes a plurality of first active regions 12a that are formed in a direction diagonal to the first direction (X direction) and are separated from each other in the first direction. The first active regions 12a are formed on the silicon layer 5 that is formed on the insulating layer 3 in the semiconductor substrate 1 as described above.

The second active regions 14a are formed to be separated from the first active regions 12a in the second direction (Y direction) that is perpendicular to the first direction. The second active regions 14a are also formed in a direction that is diagonal to the first direction like the first active regions 12a. The second active regions 14a are formed on the silicon layer 5 that is disposed on the insulating layer 3 of the semiconductor substrate 1. The first and second active regions 12a and 14a are located so that end portions thereof respectively correspond to each other in the second direction. The first and second active regions 12a and 14a are repeatedly located in the first and second directions. The memory cells 100a and 100b are realized on the first and second active regions 12a and 14a.

Word lines WL1-WL2 are formed in the second direction while crossing the first and second active regions 12a and 14a, and are separated from each other in the first direction. The word lines WL1-WL2 perform as gate electrodes by including the gate stack.

Bit lines BL1-BL2 are formed in the second direction to be parallel with the word lines WL1-WL2, and are connected to the first and second active regions 12a and 14a through bit line contacts 35. The bit lines BL1-BL2 are connected to source regions (not shown) formed in the first and second active regions 12a and 14a.

Source lines SL1-SL2 are formed in the first direction to be perpendicular to the word lines WL1-WL2 and the bit lines BL1-BL2, and are connected to the first and second active regions 12a and 14a between the word lines WL1-WL2 through source line contacts 31. The source line contact 31 may be formed on each of the memory cells 100a and 100b as shown in FIG. 9, or can be formed on the two connected memory cells 100a and 100b. The source lines SL1-SL2 are connected to drain regions (not shown) formed in the first and second active regions 12a and 14a.

According to the DRAM device of FIG. 9, one unit transistor is formed on one active region so that the memory cells 100a and 100b do not electrically interfere with each other. Moreover, in the DRAM device of FIG. 9, the first and second active regions 12a and 14a are disposed in the direction that is diagonal to the first direction (X direction), and the directions in which the bit lines BL1-BL2 and the source lines SL1-SL2 are formed are changed so that an area of the unit memory cell may be smaller than that of the previous embodiment. Cross sections of the memory cells 100a and 100b in the DRAM device of FIG. 9 will be described later with reference to accompanying, drawings.

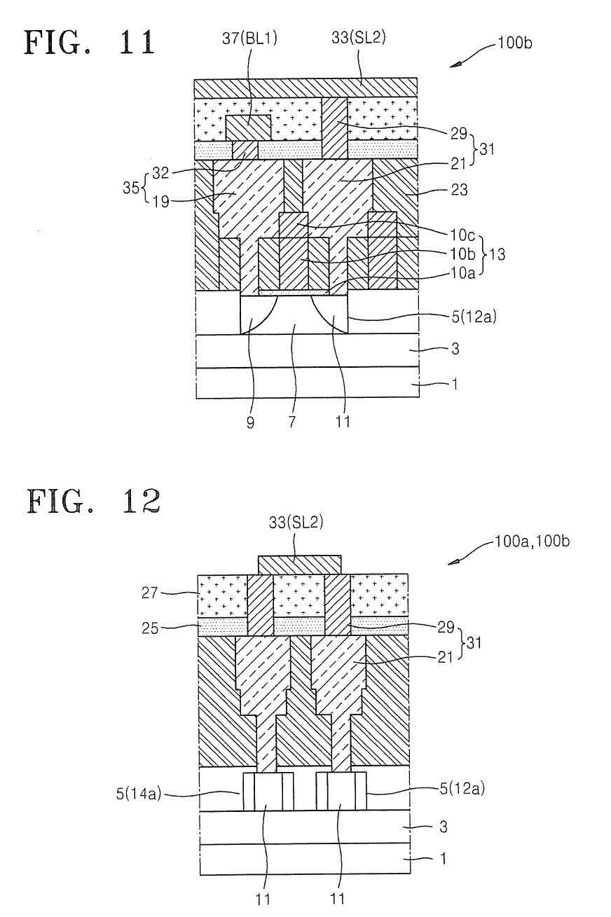

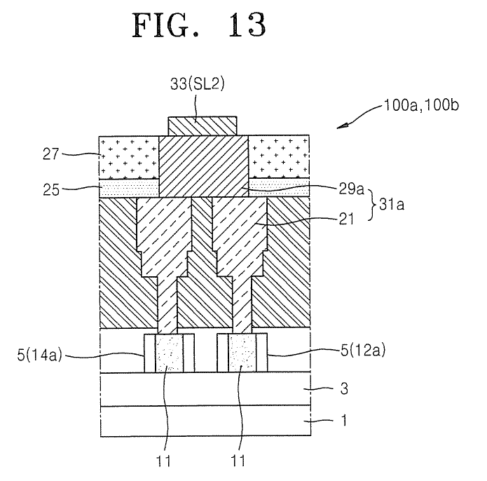

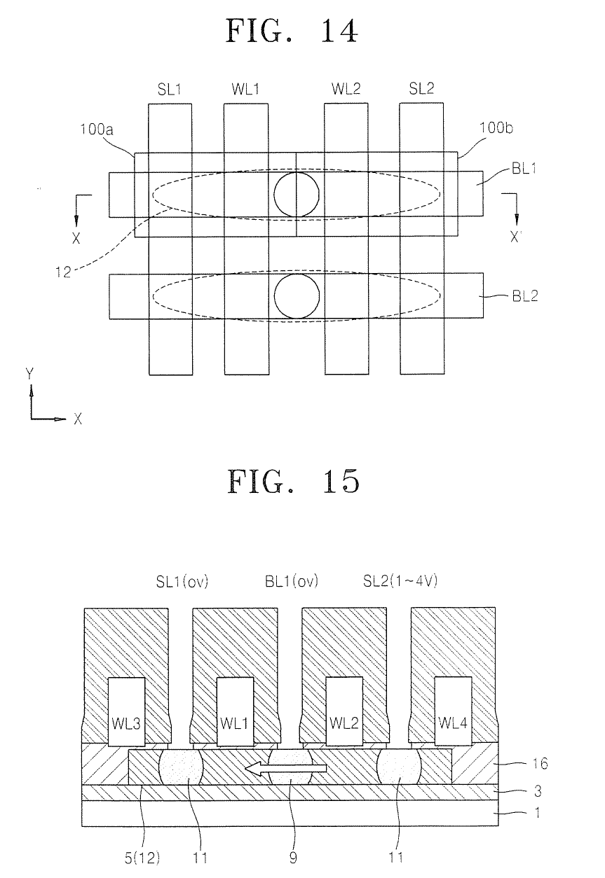

FIG. 10 is an enlarged view of a portion of the DRAM device shown in FIG. 9. FIG. 11 is a cross section of the DRAM device taken along line X-X′ of FIG. 9. FIGS. 12 and 13 are cross sections of the DRAM device taken along line Y-Y′ of FIG. 9.

In particular, formation of the source contact pad 19 and the drain contact pad 21 in the DRAM device of FIGS. 10 through 13 is similar to the device discussed above. The bit line (BL1) 37 and the source line (SL2) 33 are connected to the source contact pad 19 and the drain contact pad 21 respectively through the bit line contact pad 32 and the source line contact pad 29.

As illustrated in FIGS. 11-13, a height of the source line contact pad 29 is increased so that the source line SL2 is located on upper portion and the bit line BL1 is located on lower portion. On the other hand, according, to the DRAM device of the embodiments of the present invention discussed above, the height of the source line contact pad 29 is low so that the bit lines BL1 and BL2 are located on upper portion and the source line SL1 is located on lower portion as shown in FIGS. 6 through 8.

The source contact pad 19 and the bit line contact pad 32 form the bit line contact 35, and the drain contact pad 21 and the source line contact pad 29 form the source line contact 31. The bit line contact 35 and the source line contact 31 are insulated by the second and third interlayer dielectrics 25 and 27.

Furthermore, in FIG. 12, the source line contact pad 29 is formed on each of the memory cells 100a and 100b like in FIG. 7. That is, in FIG. 12, the source line contact pad 29 is formed on each of the memory cells 100a and 100b so that the drain contact pad 21 and the source line contact pad 29 may form the source line contact 31.

As illustrated in FIG. 13, the source line contact pad 31a is shared by the memory cells 100a and 100b like in FIG. 8. That is, the source line contact pad 29a that connects the memory cells 100a and 100b to each other so that the drain contact pad 21 and the source line contact pad 29a may form the source line contact 31a.

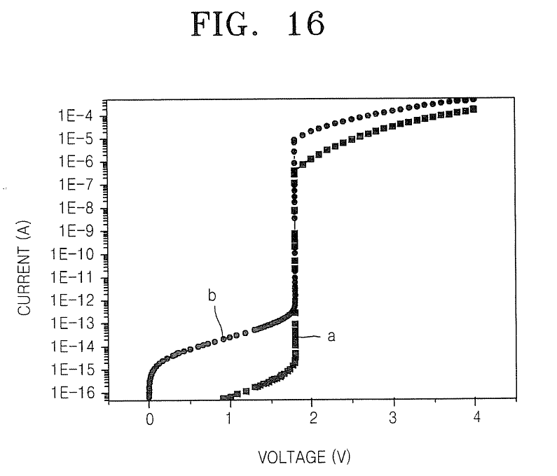

FIG. 14 is a layout of a DRAM device according to a comparative example for comparison with the DRAM device shown in FIGS. 4 and 9. FIG. 15 is a cross section of the DRAM device taken along line X-X of FIG. 14 for illustrating electric interference between memory cells in the DRAM device. FIG. 16 is a graph showing an electric current according to a voltage in the DRAM device of FIG. 14.

Referring to FIGS. 14 and 15, the DRAM device of the comparative example includes active regions 12 on the silicon layer 5 in the insulating layer 3 on the semiconductor substrate 1. The active regions are p-type silicon layers formed in the first direction (X direction). The first word line WL1 and the second word line WL2 are formed in the second direction (Y direction) to be separated from each other in the first direction across the active regions 12. The first and second source lines SL1-SL2 are located on sides of the first and second word lines WL1-WL2 along the second direction.

The source lines SL1-SL2 are connected to drain regions (11, refer to FIG. 15) formed of an n-type silicon layer. The bit line contacts 32 are formed between the first and second word lines WL1 and WL2. The bit lines BL1-BL2 are located to be perpendicular to the word lines WL1 and WL2 and the source lines SL1 and SL2 and the bit lines BL1-BL2 contact the bit line contacts 32. The bit lines BL1-BL2 are connected to source regions 9 (refer to FIG. 9) formed of the n-type silicon layer.

According to the DRAM device of the comparative example, the word lines WL1 and WL2 and the source lines SL1 and SL2 are formed in the same direction, and the bit lines BL1 and BL2 are formed perpendicularly to the word lines WL1 and WL2 and the source lines SL1 and SL2. In the DRAM device of the comparative example, two memory cells 100a and 100b are formed on one active region 12. For example, the first memory cell 100a includes the first source line SL1, the first word line WL1, and the first bit line BL1 formed on the active region 12, and the second memory cell 100b includes the second source line SL2, the second word line WL2, and the first bit line BL1 formed on the active region 12.

In the DRAM device illustrated in FIG. 14, an electric interference may occur between the first and second memory cells 100a and 100b that share the active region 12 when the DRAM device operates. That is, when a voltage of 1-4V is applied to the second source line SL2 and a voltage of −1V is applied to the second word line WL2 in order to operate the second memory cell 100b, a pnp bipolar transistor is formed as shown in FIG. 15 and an electric current flows from the second memory cell 100b to the first memory cell 100a, and thus, the first memory cell 100a starts operating.

The above electric interference is shown in the graph showing the current according to the voltage in FIG. 16. When a voltage of 0V is applied, a current flows through the second source line SL2 as denoted by character a, and when the applied voltage increases, the current also flows through the first source line SL1, which is included in the first memory cell 100a. Therefore, a defect may be generated.

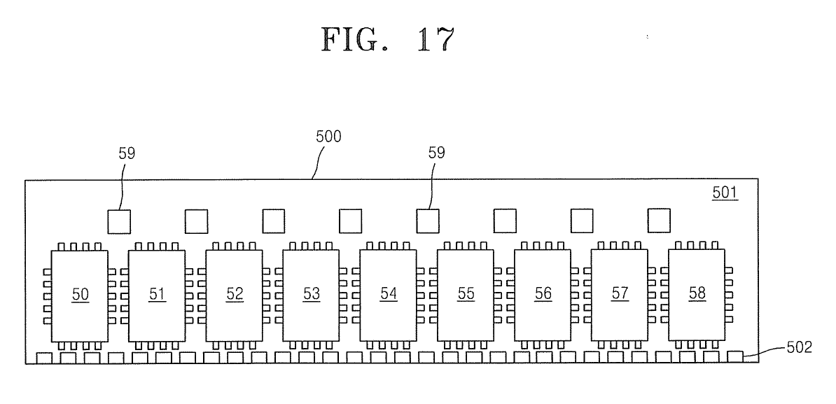

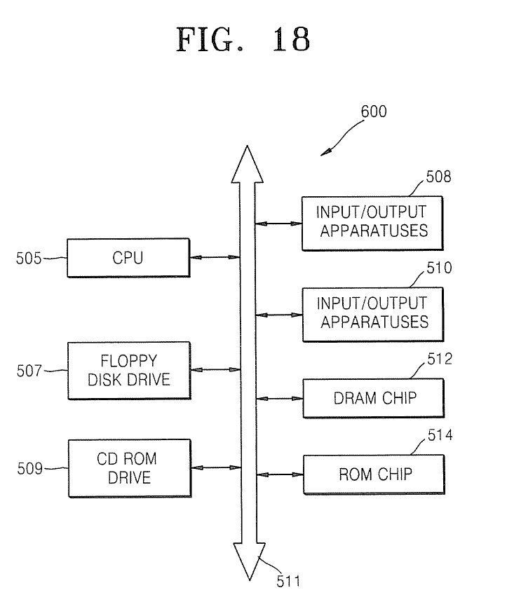

Various applications of the DRAM device according to some embodiments of the present invention will be discussed with respect to FIGS. 17 and 18. The DRAM device is packaged to form a DRAM chip.

FIG. 17 is a plan view of a memory module using the DRAM chip according to some embodiments of the present invention. In particular, DRAM chips 50-58 are formed by packaging the DRAM device of some embodiments of the present invention. The DRAM chips 50-58 are applied to a memory module 500. The memory module 500 includes a module substrate 501, to which the DRAM chips 50-58 are attached. A connection portion 502, which can be inserted into a socket of a mother board, is located on a side of the module substrate 501, and ceramic decoupling capacitors 59 are located on the module substrate 501. The memory module is not limited to the structure shown in FIG. 12, and may be modified variously.

FIG. 18 is a block diagram of an electronic system using the DRAM chip according to some embodiments of the present invention. In particular, the electronic system 600 may be a computer. The electronic system 600 includes a central processing unit (CPU) 505, a floppy disk drive 507, a compact disk read only memory (CD ROM) drive 509, input/output apparatuses 508 and 510, a DRAM chip 512, and a ROM chip 514. The above components transmit/receive control signals or data using a communication channel 511. The DRAM chip 512 of FIG. 18 may be substituted by the memory module 500 including the DRAM chips 50-58 shown in FIG. 17.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A dynamic random access memory (DRAM) device comprising:
an insulating layer on a semiconductor substrate;
a silicon layer on the insulating layer;
an active region in the silicon layer; and
a unit cell of a transistor on the active region, the DRAM device not including a capacitor.

2. The DRAM device of claim 1, wherein the unit cell of the transistor comprises:
a gate stack on the active region;
a source region and a drain region in the silicon layer under both walls of the gate stack;
a body region between the source region and the drain region;
a source contact pad and a drain contact pad on the source region and the drain region, respectively; and
a bit line and a source line connected to the source contact pad and the drain contact pad, respectively.

3. The DRAM device of claim 2, wherein the body region is electrically floated by junctions between the source/drain regions and the body region, and by the insulating layer.

4. A DRAM device comprising:
an insulating layer on a semiconductor substrate;
a plurality of silicon layers on the insulating layer;
a plurality of first active regions in the silicon layers on the insulating layer in a first direction;
a plurality of second active regions in a second direction to be separated from the first active regions in the first direction, wherein the first direction is perpendicular to the second direction;
a plurality of word lines in the second direction across the plurality of first active regions and the plurality of second active regions and separated from each other in the first direction;
a plurality of source lines between the word lines to be parallel with the word lines and connecting to some parts of the first active regions and the second active regions between the word lines; and
a plurality of bit lines in the first direction along with the first and second active regions and connecting to some parts of the first and second active regions, the DRAM device not including a capacitor.

5. The DRAM device of claim 4, wherein the source lines are connected to source line contacts in the first active regions and the second active regions located on side portions of the word lines.

6. The DRAM device of claim 4, wherein the bit lines are connected to bit line contacts in the first active regions and the second active regions located on side portions of the word lines.

7. The DRAM device of claim 6, wherein the bit line contacts are source contact pads that are on the first and second active regions and bit line contact pads on the source contact pads.

8. A DRAM device comprising:
an insulating layer on a semiconductor substrate;
a plurality of silicon layers on the insulating layer;
a plurality of first active regions in a direction that is diagonal to a first direction, which is parallel with the silicon layers on the insulating layer, and separated from each other in the first direction;
a plurality of second active regions separated from the first active regions in a second direction that is perpendicular to the first direction;
a plurality of word lines in the second direction across the first and second active regions and separated from each other in the first direction;
a plurality of bit lines in the second direction and connecting to the first and second active regions through bit line contacts; and
a plurality of source lines to be perpendicular to the word lines and the bit lines and connecting to the first and second active regions between the word lines throuh source line contacts, the DRAM device not including a capacitor.

9. The DRAM device of claim 8, wherein the source line contacts are drain contact pads on the first and second active regions and source line contact pads on the drain contact pads.

10. The DRAM device of claim 8, wherein the bit line contacts are in the second direction along with the first and second active regions, and the source line contacts are in the first direction along with the first and second active regions.
